(19) United States
(12) Patent Application Publication
(10) Pub. No.: US 2026/0130249 A1
(43) Pub. Date: May 7, 2026

(54) SEMICONDUCTOR MODULE WITH POWER BRIDGE FOR INTEGRATED DIE INTERCONNECTION

(71) Applicant: SEMICONDUCTOR COMPONENTS INDUSTRIES, LLC, Scottsdale, AZ (US)

(72) Inventors: Christopher Lee TESSLER, Poughquag, NY (US); Michael J. SEDDON, Gilbert, AZ (US); Dinesh RAMANATHAN, Los Altos Hills, CA (US); Anders Soren LIND, San Juan Capistrano, CA (US); Vijay B. RENTALA, Plano, TX (US)

(73) Assignee: SEMICONDUCTOR COMPONENTS INDUSTRIES, LLC, Scottsdale, AZ (US)

(21) Appl. No.: 19/376,699

(22) Filed: Oct. 31, 2025

Related U.S. Application Data
(60) Provisional application No. 63/715,912, filed on Nov. 4, 2024.
(60) Provisional application No. 63/736,415, filed on Dec. 19, 2024.

(51) Int. Cl. H01L 23/538; H01L 23/34; H01L 25/065

(52) U.S. Cl. CPC H10W 70/65; H10W 40/00; H10W 70/611; H10W 70/614; H10W 90/00

(57) ABSTRACT

A semiconductor module may include a first substrate having a first substrate surface that includes an area, a first semiconductor die disposed within the area on the first substrate surface, and a second semiconductor die disposed within the area on the first substrate surface. The semiconductor module may further include a second substrate that has a second substrate surface that spans the area and faces the first semiconductor die, the second semiconductor die, and the area, with the second substrate surface having a dielectric layer formed thereon with a metallization layer formed on the dielectric layer that includes patterned metals configured to electrically connect the first semiconductor die and the second semiconductor die to each other and to at least one conductive element on the first substrate surface that is outside of the area.

### CROSS-REFERENCE TO RELATED APPLICATION

This application claims the benefit of and priority to (1) U.S. Provisional Application No. 63/715,912, filed Nov. 4, 2024, and (2) U.S. Provisional Application No. 63/736,415, filed Dec. 19, 2024, and to U.S. Non-provisional application xx/xxx,xxx, filed concurrently herewith and titled SEMICONDUCTOR PACKAGING WITH EMBEDDED DEVICE AND REDISTRIBUTION LAYER, which are incorporated by reference herein in their entireties.

### TECHNICAL FIELD

This description relates to power semiconductor devices.

### BACKGROUND

Conventional power semiconductor modules may utilize wire bonds to establish interconnects between a die and the package and/or between individual dies. However, wire bonds are associated with a number of shortcomings, including, e.g., elevated inductance and resistivity, which may impair switching performance. Moreover, wire bonds tend to consume undesirable quantities of space, may be unreliable, and, once connected, are difficult to revise or rework.

Another widely adopted technique involves die embedding within power semiconductor packages. Such approaches provide electrical access to both the top and bottom of the power die, which may enhance connectivity. Such methods, while effective for two-sided access, also introduce process complexities, as well as difficulties in ensuring uniform electrical properties across multiple parallel dies, and may therefore struggle with providing synchronized switching, e.g., in half-bridge configurations. The inability to test and tune resistance and inductance prior to assembly limits the optimization of such modules under demanding conditions.

Traditional packaging for power devices often fails to provide desired levels of reliability, as well. For example, differences in thermal expansion characteristics between a die and a package (e.g., ceramic) may result in cracking or other failures.

Further, known techniques struggle to meet demand with respect to manufacturing compact devices that also provide desired thermal management. For example, heatsinks that provide sufficient heat dispersal are often too large to provide a final package of desired size. Further, mold materials or organic materials used in embedded packages tend to be poor heat conductors.

The above difficulties, and others, are exacerbated by the need to produce power devices at scale. As a result, current power devices and associated packaging techniques are unable to meet market demand.

### SUMMARY

According to one general aspect a semiconductor module, comprises a first substrate having a first substrate surface that includes an area, a first semiconductor die disposed within the area on the first substrate surface, a second semiconductor die disposed within the area on the first substrate surface, and a second substrate that has a second substrate surface that spans the area and faces the first semiconductor die, the second semiconductor die, and the area, the second substrate surface having a dielectric layer formed thereon with a metallization layer formed on the dielectric layer that includes patterned metals configured to electrically connect the first semiconductor die and the second semiconductor die to each other and to at least one conductive element on the first substrate surface that is outside of the area.

According to another general aspect, a semiconductor module, comprises a first substrate having a first substrate surface that includes an area, a first semiconductor die disposed within the area on the first substrate surface and having a first height, a second semiconductor die disposed within the area on the first substrate surface and having a second height, a second substrate that has a second substrate surface that spans the area and faces the first semiconductor die, the second semiconductor die, and the area, the second substrate surface having a dielectric layer formed thereon with a metallization layer formed on the dielectric layer that includes patterned metals configured to electrically connect the first semiconductor die and the second semiconductor die to each other, and a height adjustment structure between the second substrate and both of the first semiconductor die and the second semiconductor die that maintains opposed outer surfaces of the semiconductor module in parallel with one another.

According to another general aspect, a method of making a semiconductor module, comprises disposing, on a first substrate having a first substrate surface that includes an area, a first semiconductor die and a second semiconductor die disposed within the area on the first substrate surface, forming a second substrate with a second substrate surface having a dielectric layer formed thereon with a metallization layer formed on the dielectric layer that includes patterned metals, and connecting the second substrate to the first substrate, with the second substrate surface of the second substrate spanning the area and facing the first semiconductor die and a second semiconductor die within the area, and with the patterned metals configured to electrically connect the first semiconductor die and the second semiconductor die to each other and to at least one conductive element on the first substrate surface that is outside of the area.

The details of one or more implementations are set forth in the accompanying drawings and the description below. Other features will be apparent from the description and drawings, and from the claims.

### BRIEF DESCRIPTION OF THE DRAWINGS

FIG. 1 is an exploded side view illustrating example embodiments of a semiconductor module with a power bridge for integrated die interconnection.

FIG. 2 is a cross-sectional side view of an example implementation of the semiconductor module of FIG. 1.

FIG. 3 illustrates a view of the example implementation of FIG. 2, taken along line AA.

FIG. 4 illustrates a view of the example implementation of FIG. 2, taken along line BB.

FIG. 5A is a top view of a first example semiconductor module made in accordance with the example embodiments of FIGS. 1-4.

FIG. 5B is a cross-sectional view of the example implementation of FIG. 5A, taken along line 5B.

FIG. 6A is a top view of a second example semiconductor module made in accordance with the example embodiments of FIGS. 1-4.

FIG. 6B is a cross-sectional view of the example implementation of FIG. 6A, taken along line 6B.

FIG. 7A illustrates first example operations for manufacturing the example implementation of FIGS. 2-4.

FIG. 7B illustrates first example operations for manufacturing the example implementation of FIGS. 2-4.

FIG. 7C illustrates first example operations for manufacturing the example implementation of FIGS. 2-4.

FIG. 7D illustrates first example operations for manufacturing the example implementation of FIGS. 2-4.

FIG. 7E illustrates first example operations for manufacturing the example implementation of FIGS. 2-4.

FIG. 7F illustrates first example operations for manufacturing the example implementation of FIGS. 2-4.

FIG. 7G illustrates first example operations for manufacturing the example implementation of FIGS. 2-4.

FIG. 8 is a cross-sectional side view of an alternate example implementation of the semiconductor module of FIG. 1.

FIG. 9 is a cross-sectional side view of the example implementation of FIG. 8, illustrating an example encapsulation.

FIG. 10 is a cross-sectional side view of the example implementation of FIG. 8, illustrating a first example of embedded packaging.

FIG. 11 is a cross-sectional side view of the example implementation of FIG. 8, illustrating a second example of embedded packaging.

FIG. 12 is a process flow for wafer-level processing of power bridges of FIG. 1.

FIG. 13 is a flowchart illustrating example manufacturing techniques for a semiconductor package that includes the power bridges of FIG. 1.

### DETAILED DESCRIPTION

Described power semiconductor packaging techniques enable improvements to the above and other shortcomings of conventional techniques. For example, described techniques provide enhanced inductance/resistivity, improved module reworkability, synchronized die switching, pre-assembly testing and tuning, and simplified two-sided electrical/thermal access. Described techniques provide more compact and more reliable packages, while providing enhanced reliability and thermal management, among other advantages.

In described techniques, semiconductor dies may be distributed and positioned in a desired manner across an area of a first substrate. Then, a second substrate may be positioned above the first substrate, spanning the area of the first substrate containing the dies to be connected. The second substrate may be manufactured with a dielectric layer and metallization layer in a pattern that enables desired connections among the spanned dies, as well as with other elements on the first substrate that are outside the footprint of the area spanned by the second substrate. Then, the second substrate may be positioned above the defined area, and attached to the underlying dies, and to the first substrate itself.

In this way, the second substrate (that is, the included metallization layer(s)) may replace wirebonds or other conventional interconnect techniques. Further, a top surface of the second substrate may be kept parallel to a surface of the first substrate, so that, similar to conventional embedding techniques, two-sided connectivity may be provided. Put another way, outer, opposed surfaces of the first substrate and the second substrate may be maintained in parallel with one another.

The second substrate (and attached wiring), also referred to as a power bridge, resolves difficulties of inconsistent electrical properties typical in known techniques. For example, the patterned metals on the second substrate that electrically connect underlying dies to each other and to conductive elements outside the designated area ensure uniform switching behavior that is important, e.g., for half-bridge configurations, while offering a reliable interconnection network that enhances overall module performance under demanding conditions. The metallization layer on the dielectric of the second substrate provides a robust interconnection network, addressing the difficulty of integrating multiple parallel devices with uniform characteristics.

Described techniques also address the challenge of pre-assembly testing and tuning, e.g., by enabling individual die evaluation before integration. For example, this allows for adjustments to resistance and inductance prior to final assembly, reducing the risk of performance degradation and improving reliability in high-power environments. Even if testing identifies a failure of desired quality assurance standards, the second substrate may be removed to enable further modifications of installed dies, after which the second substrate may be reinstalled, thereby providing reworkability that is not possible in conventional techniques.

In addition to providing two-sided electrical connectivity, the two-sided access provided by the spanning second substrate supports effective thermal dissipation, as well. For example, when a surface of the second substrate is kept parallel to a surface of the first substrate and exposed, a heatsink may easily be installed thereon.

The second substrate may be provided using Silicon, or variations thereof (e.g., Silicon Carbide (SiC)). As a result, active or passive devices may be included in the second substrate, thereby adding flexibility to available design choices for a module, while further decreasing the module size.

In many cases, height differences may exist between the various semiconductor dies on the first substrate. A height adjustment structure(s) may be used between the dies and the second substrate to accommodate such height differences. For example, one or more cavities may be formed in the second substrate, so that a first, taller die may be disposed within a deeper cavity than a second, shorter die. In other examples, the height adjustment structures may include additional connecting layers between the dies and the second substrate, such that fewer additional layers may be disposed between a first, taller die and the second substrate than between a second die and the second substrate. As a result, for example, a top surface of the second substrate may be maintained in parallel with a surface of the first substrate, to facilitate electrical and/or thermal connectivity with respect to the second substrate, as referenced above.

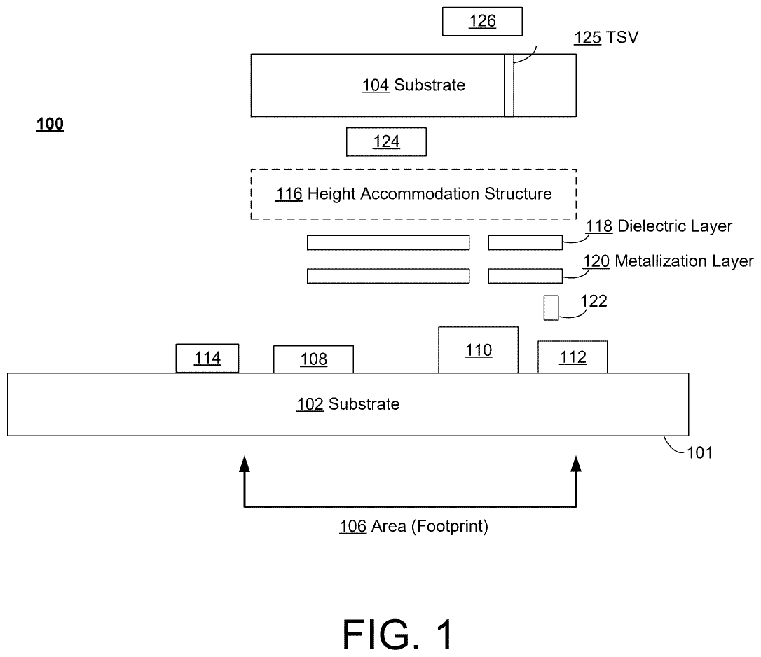

FIG. 1 is an exploded side view illustrating example embodiments of a semiconductor module 100 with a power bridge for integrated die interconnection. In the example of FIG. 1, a substrate 102 represents a first substrate of the semiconductor module 100, which may be made of any suitable substrate material, including, e.g., Si, SiC, Gallium Nitride (GaN), ceramic, or DBM. Other example substrate materials are provided below, or would be apparent. In some implementations, a bottom surface 101 of the first substrate 102 may be exposed for electrical and/or thermal connectivity, as referenced above and described in more detail, below.

A second substrate 104 is positioned over an area 106 of the first substrate 102. The second substrate 104 has a size and associated perimeter/dimensions that span the area 106 and/or may be said to have or a footprint with respect to the first substrate 102 that is defined by the area 106. For example, although shown in two dimensions in the cross-sectional view of FIG. 1, the second substrate 104 (and thus the area 106) may be any available shape, such as a square, or a rectangle.

The second substrate 104 may be formed or may include, a semiconductor substrate. That is, the second substrate 104 may be formed using any material usable for forming semiconductor devices, including, for example, Si, SiC, or GaN. As described herein, forming the second substrate using such a semiconductor material provides a number of advantages, including, e.g., using fabrication techniques commonly used with such materials, as well as the ability to form one or more semiconductor devices in and/or on such materials.

A first semiconductor die 108 and a second semiconductor die 110 are positioned on the first substrate 102 and disposed within the area 106. Other elements may be disposed on the first substrate 102, as well. For the sake of example, an element 112 and an element 114 are illustrated, with the element 112 being disposed partially within the area 106, and the element 114 being disposed entirely outside of the area 106. The semiconductor dies 108, 110 may represent, e.g., any suitable power semiconductor device, such as an insulated gate bipolar transistor (IGBT) or a metal oxide semiconductor field effect transistor (MOSFET). The elements 112, 114 may represent any passive or active element that may be included in the semiconductor module 100, including any conductive element (including metallization layers) that may be disposed on the first substrate 102.

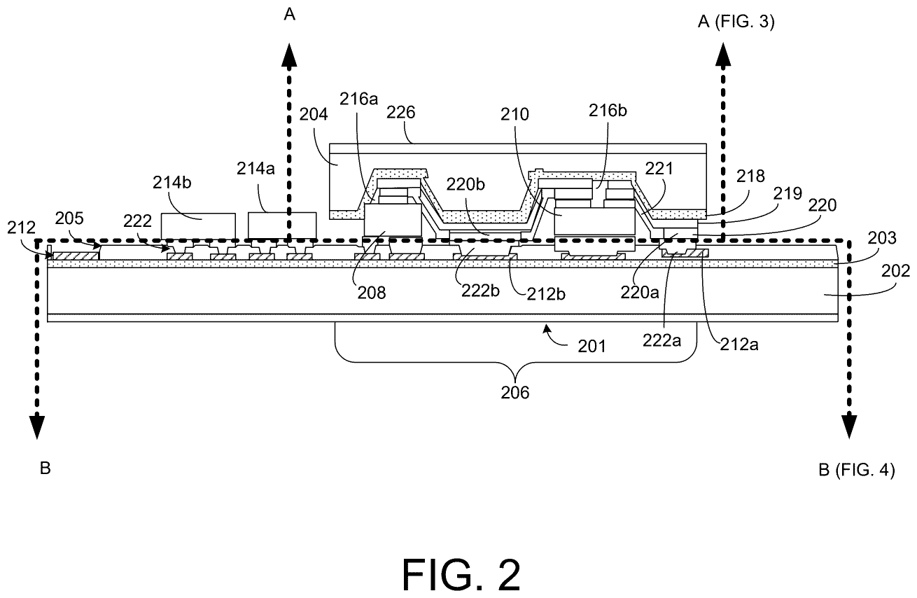

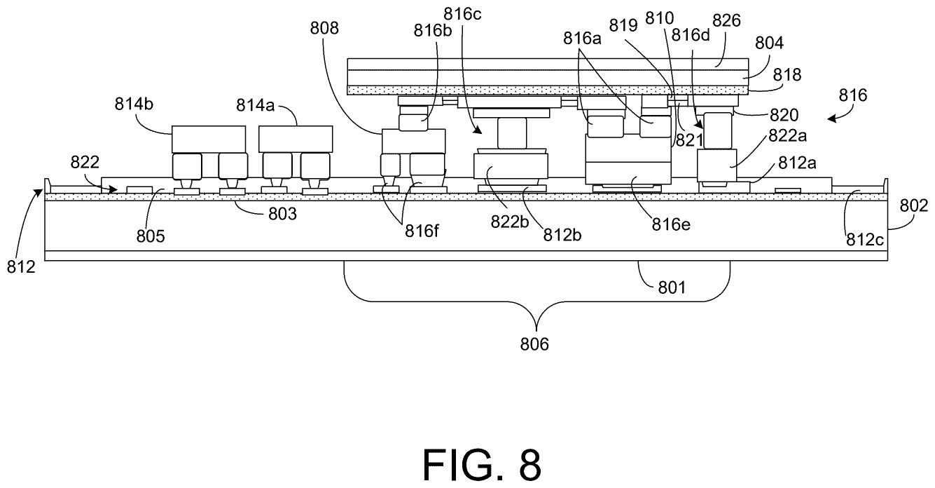

As referenced above, and shown in FIG. 1, the semiconductor dies 108, 110 (or additional dies) may have different heights. A height accommodation structure 116 may be included to account for such height differences. For example, as shown in the examples of FIGS. 2-7H, the height accommodation structure 116 may include cavities formed in the material of the second substrate 104. In other examples, as shown in the examples of FIGS. 8-11, the height accommodation structure 116 may include layers selectively added for each of the semiconductor dies 108, 110. For example, plating or other conductive layers may be added to the second substrate 104. In the example of FIG. 1, more such layers may be added in conjunction with the semiconductor die 108 than with the semiconductor die 110, since the semiconductor die 110 has a greater relative height. Using these or other suitable height accommodation structure(s), the second substrate 104 may be maintained with a top surface thereof in parallel with a top surface of the first substrate 102. Put another way, outer, opposed surfaces of the first substrate 102 and the second substrate 104 may be maintained in parallel with one another.

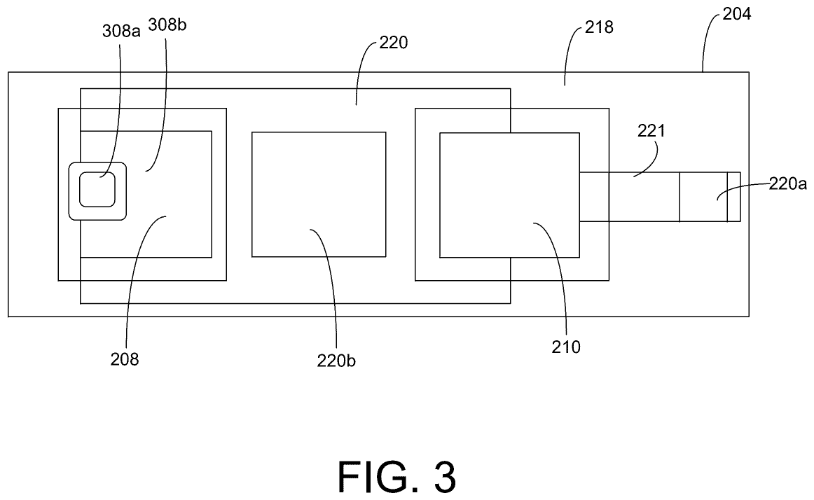

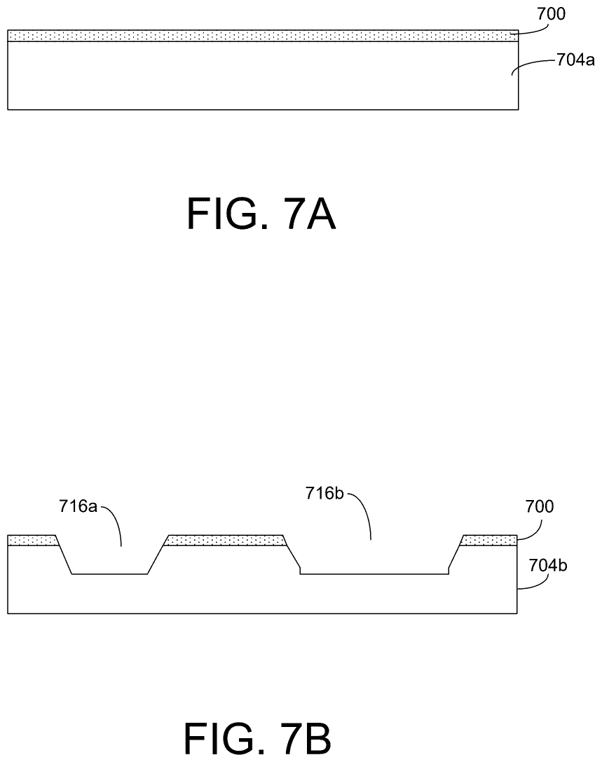

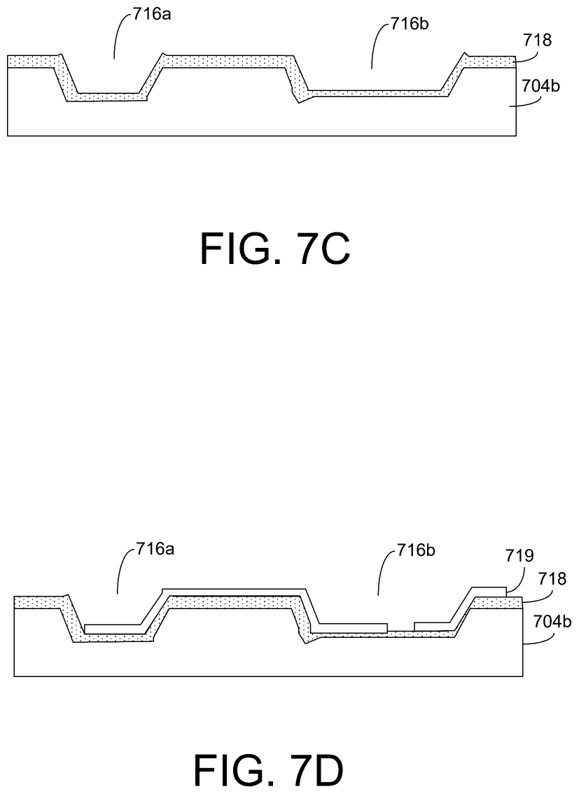

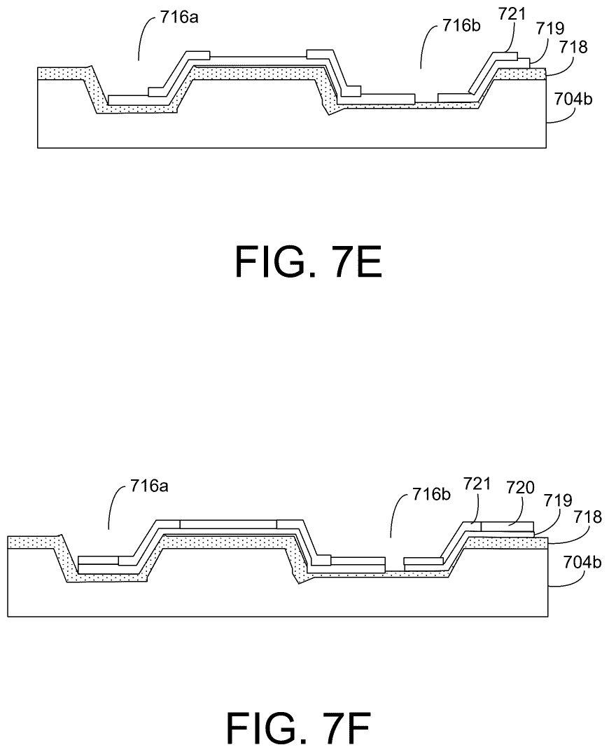

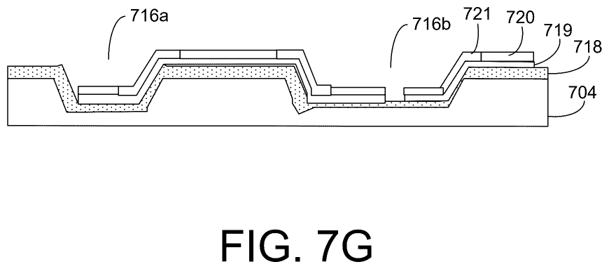

In order to provide interconnection of the semiconductor dies 108, 110, to one another and to one or more of the elements 112, 114, a dielectric layer 118 and associated metallization layer 120 may be disposed on the second substrate 104. As illustrated in more detail in FIG. 3, and FIGS. 7A-7G, any desired pattern of metallization 120 may thus be deposited onto the second substrate 104, thereby enabling any corresponding connections between, e.g., the semiconductor dies 108, 110 and the conducting element 112.

For example, such patterning may be performed with respect to the second substrate 104, and then the second substrate 104 may be aligned with the area 106 and deposited thereover, thus simultaneously connecting the semiconductor dies 108, 110 and the conductive element 112. For example, a direct connection 122 (e.g., solder or sinter) may be formed between the metallization layer 120 and the conductive element 112, so that the second substrate 104 is physically connected to the first substrate 102. In addition, if desired or needed, the second substrate 104 may be removed from the first substrate 102, and subsequently reconnected.

Using these and related techniques, the semiconductor module 100 may be provided with the types of tuning and reworkability features referenced above. For example, the metallization layer 120 may be formed and/or trimmed in a desired manner, so that relative inductances and/or resistivities may be obtained, and the semiconductor dies 108, 110 (and other dies included within the area 106) may operate in desired synchronization with one another. In the event that desired results are not achieved, the second substrate 104 may be removed. Then, reworking of any exposed elements may be performed, and the second substrate 104 may be reattached. These processes may be continued until the semiconductor module 100 is ready for deployment.

In addition, many additions and/or modifications may be made with respect to the second substrate 104. For example, when the second substrate 104 is made of, or includes, Si, additional elements illustrated as element 124 and element 126 may be included in, with, or on the second substrate using standard techniques.

For example, either or both of the element 124 and element 126 may represent any passive or active circuit element that may be used in the context of the semiconductor module 100. For example, the element 124 or the element 126 may represent a temperature sensor. By placing a temperature sensor on the second substrate 104, rather than on an exposed surface of the first substrate 102, an overall device size may be reduced, and precise temperature sensing may be provided. In other examples, as referenced above, the element 126 may include a heatsink or other thermal management solution.

Further, a through-Silicon via (TSV) 125 may be formed through the second substrate 104. For example, the TSV 125 may be used to connect the elements 124, 126 to one another, or may be used to connect the element 126 to elements on a surface of the first substrate 102, such as the semiconductor die 110. One or both of the elements 124, 126 may represent a conductive element or layer used for connective purposes.

Further, in some embodiments, a stacked arrangement may be made by adding a third (or more) substrate as a second power bridge for the second substrate 104/first power bridge. In such embodiments, the TSV 125 may enable connection between the power bridges, and/or between the third substrate/second power bridge and the first substrate 102.

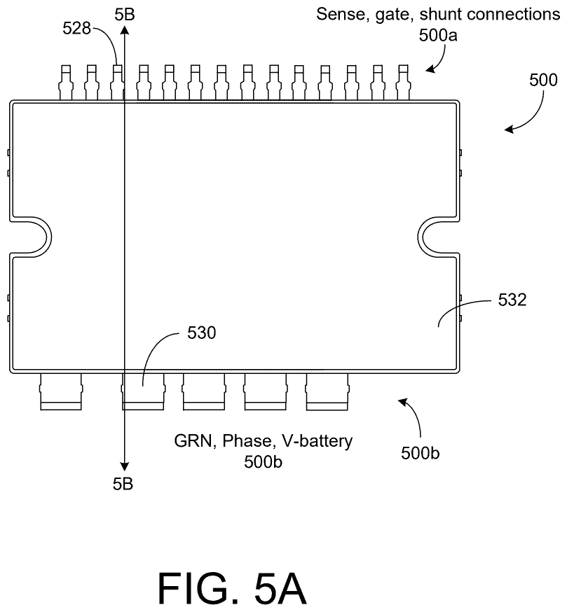

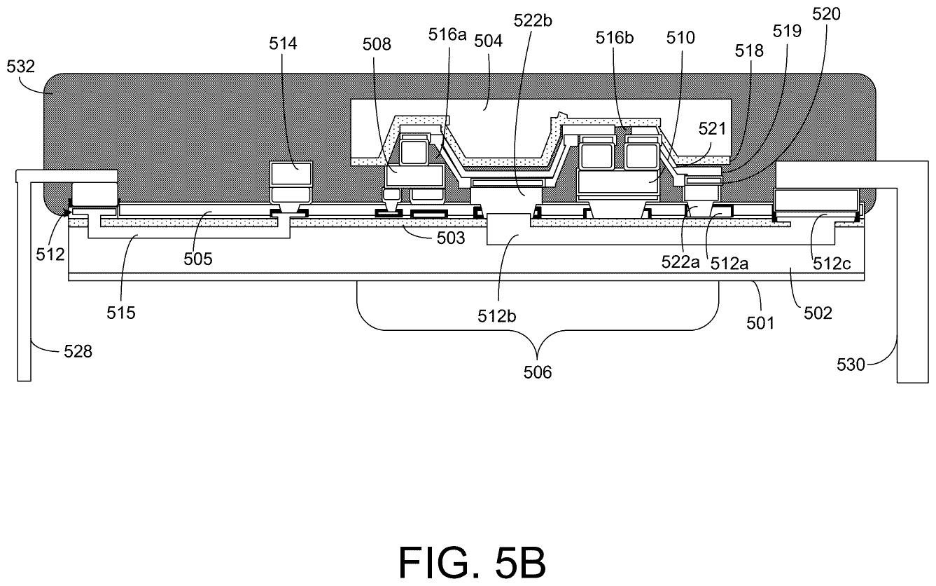

Although not illustrated in the simplified example of FIG. 1, the semiconductor module 100 may be encapsulated using any suitable encapsulant. For example, any suitable epoxy may be used, as shown in the example of FIGS. 5, 6, and 9. In other examples, an embedded package may be constructed using a suitable material, such as an organic material. For example, Flame Retardant 4 (FR-4), a glass-reinforced epoxy laminate, may be used. Advantageously, virtually any of these embodiments may be implemented with the possibility of electrical and/or thermal connectivity to the first substrate 102 and/or the second substrate 104.

FIG. 2 is a cross-sectional side view of an example implementation of the semiconductor module of FIG. 1. That is, FIG. 2 illustrates an example assembled version of the exploded side view the semiconductor module 100 of FIG. 1. For example, the embodiment of FIG. 2 may represent a portion of an inverter module, or other power module.

In the example of FIG. 2, a substrate 202 represents a first substrate, as an example of the first substrate 102 of FIG. 1. As with FIG. 1, in some implementations, a bottom surface of the first substrate 202 may be exposed for electrical and/or thermal connectivity, using an interconnect 201. For example, the interconnect 201 may represent, or include, a metal layer, such as when the first substrate 202 is a DBM. In other examples, a back metal layer may be soldered or sintered as the interconnect 201. In other examples, an epoxy interconnect may be used.

A second substrate 204 is positioned over an area 206 of the first substrate 202, defining a span or footprint with respect to the first substrate 202, as discussed above. A first semiconductor die 208 and a second semiconductor die 210, which may both represent IGBTs in the example of FIG. 2, are positioned on the first substrate 202 and disposed within the area 206.

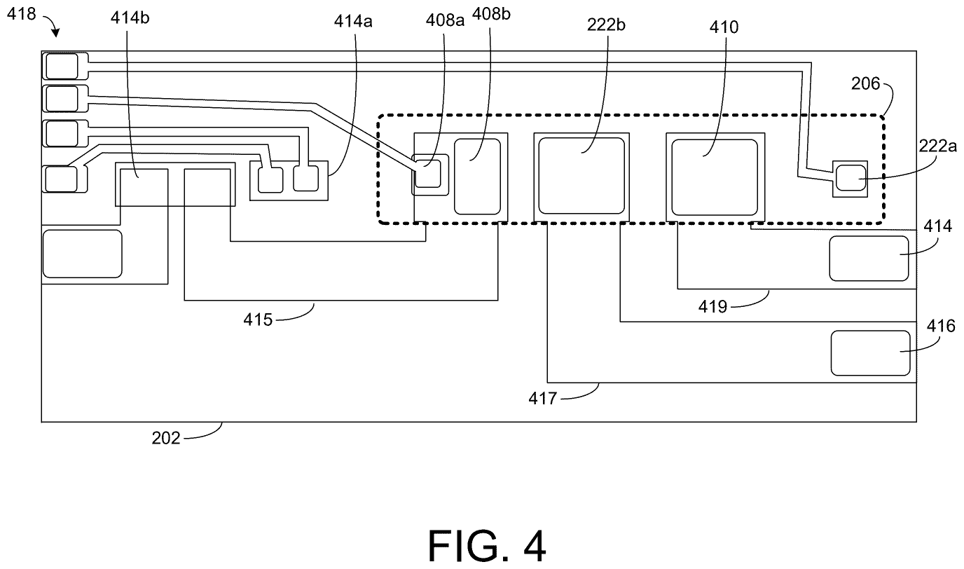

In the example of FIG. 2, a conductive element 212a and a conductive element 212b are illustrated as metallization or interconnects. As described with respect to the element 112 of FIG. 1, one or both of the conductive elements 212a, 212b may extend outside of the area 206, e.g., in the plane of the cross-section of FIG. 2 and/or in a direction perpendicular to that plane, as shown in more detail in FIG. 4, thereby facilitating and enabling connection(s) between the dies 208, 210 and other elements of the semiconductor module of FIG. 2.

An element 214a is illustrated as a negative temperature coefficient/thermistor, also referred to as a NTC sensor 214a, while a second element 214b is illustrated generally as a passive circuit element. As described with respect to FIG. 1, the elements 214a, 214b generally represent any element(s) that may be disposed on the first substrate 202 and entirely outside of the area 206. Advantageously, in described embodiments, such elements may be provided more flexibly than in conventional techniques. For example, the NTC sensor 214a may be placed very close to the dies 208, 210, i.e., closer than in conventional techniques. As also referenced, the NTC sensor 214a or other elements may be disposed in or on the second substrate 204, as well.

As referenced above, the semiconductor dies 208, 210 in FIG. 2 have different heights. As an example implementation of the height accommodation structure 116 of FIG. 1, a cavity 216a and a cavity 216b are illustrated as containing the dies 208, 210, and having respective depths to ensure that a heat sink 226, and an underlying surface of the second substrate 204, are maintained as being level with, or parallel to, a surface(s) of the first substrate 202, such as a top or bottom surface thereof, and/or parallel with the interconnect 201, e.g., a back metal layer. In particular, the die 208 is taller or higher than the die 210 in FIG. 2, so that the cavity 216a is slightly deeper than the cavity 216b within the second substrate 204. A width and/or length of each of the cavities 216a, 216b may be constructed to fit with, or accommodate, corresponding dimensions of respective dies 208, 210, as well.

In order to provide interconnection of the semiconductor dies 208, 210, to one another and to one or more of the elements 212a, 212b, a dielectric layer 218, metallization layer 219, metallization layer 220, and dielectric layer 221 may be disposed on the second substrate 204. In particular, a portion 220a of the metallization layer 220 may be connected to a direct connection 222a, e.g., may be soldered or sintered to conductive element 212a. Similarly, a portion 220b of the metallization layer 220 may have a direction connection 222b, e.g., may be soldered or sintered, to a conductive element 212b that may extend outside of the area 206.

More generally in FIG. 2, the first substrate 202 has a dielectric layer 203 formed thereon, which has a metallization layer 212 that includes conductive elements 212a, 212b. Connections 222 (e.g., solder, sinter), including the described connections 222a, 222b connecting the second substrate 204 to the first substrate 202, are formed through dielectric layer 205 to also attach the dies 208, 210 to the first substrate, as well as to attach the NTC sensor 214a and the passive element 214b to the first substrate 202.

Thus, as described with respect to FIG. 1, direct connection of the second substrate 204 to the first substrate 202, in addition to the connection thereof through connection to the dies 208, 210, provides a reliable connection. At the same time, such an approach enables removal of the second substrate 204 if needed to rework any aspect of the second substrate 204 and/or the dies 208, 210 or other elements within the area 206.

For example, the second substrate 204 may be removed using a ‘hot pull’ process, in which heat is used to soften a solder or other adhesive, allowing the second substrate 204 to be lifted off of the first substrate 202. Then, metal (e.g., copper) dressing or other cleaning/reshaping processes may be used to modify exposed metal/copper surfaces exposed, ensuring such surfaces are smooth and ready for reattachment.

The sloped or angled walls of the cavities 216a, 216b enable and facilitate depositing of the dielectric layer 218, metallization layer 219, and metallization layer 220. Thus, the sloped or angled walls of the cavities 216a, 216b facilitate the types of patterned interconnects described herein for connecting the dies 208, 210 to one another and to other conductive elements that may lie partially or completely outside of the area 206.

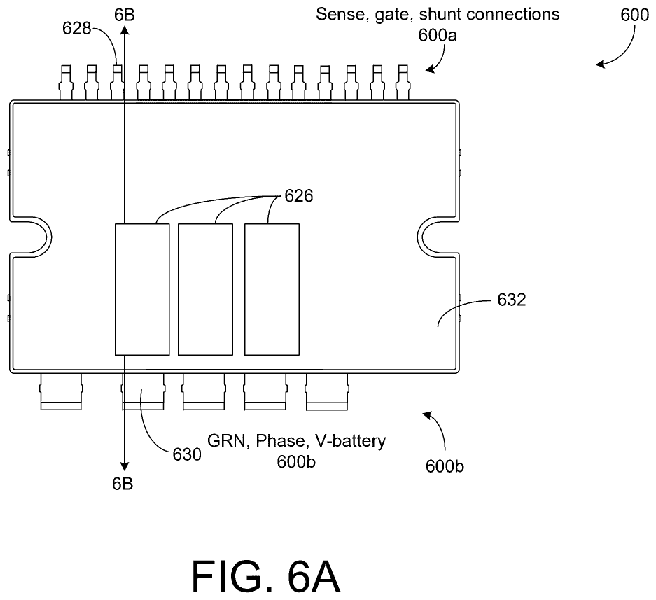

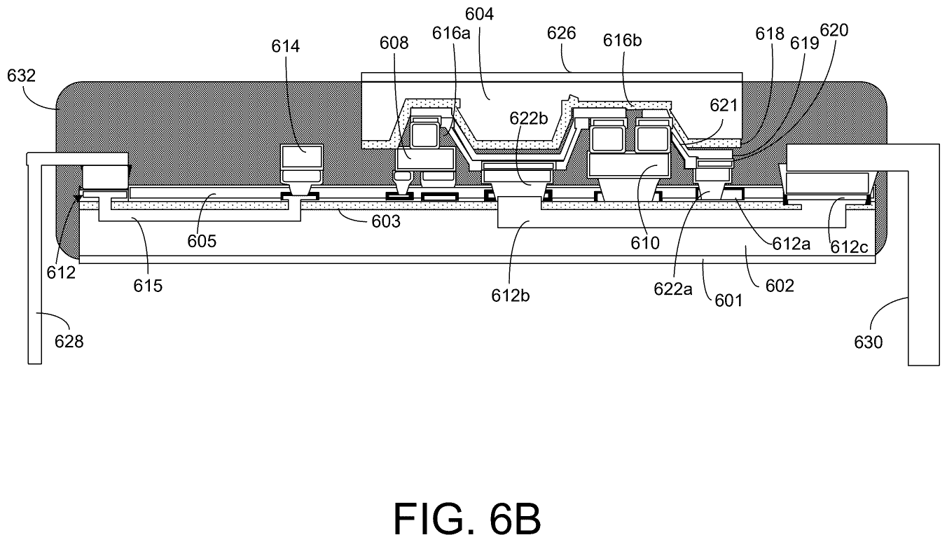

In FIG. 2, the metallization layer 212 of the first substrate 202 may contain any standard interconnects and associated elements, including, e.g., one or more dielectrics and conductors (e.g., contact pads or metal layers), as well as attachment points for attaching a lead frame or other package element, as shown below in FIGS. 5B and 6B. Once assembled, the module of FIG. 2 is thus ready for lead frame attach, heat sink attach, encapsulation, or other processing, as described and illustrated in more detail, below, with respect to FIGS. 5A-6B.

Thus, the example of FIG. 2 illustrates the use of the second substrate 204 and associated features as a power bridge for a semiconductor module, such as a power semiconductor module, that replaces wire bonds, ribbon bonds, clips, and other conventional interconnection techniques for connections between multiple dies and/or between a die(s) and a package. Such a power bridge enables improved assembly efficiency and avoids resistance losses from electrical crowding of current flowing into a wire bond. The power bridge thus provides connections with improved inductance, resistivity, tunability, and reworkability. Resulting modules may be more compact (in length, width, and height), providing more functionality per area than conventional modules. Further, resulting modules are more reliable than conventional modules, e.g., may be less susceptible to damage from different rates of thermal expansion of components within the module than conventional modules.

Specifically, for example, the described power bridge enables matching of electrical properties within and among power dies on a module, e.g., for simultaneous switching, which is important in many applications (e.g., for acceleration of an electric vehicle). To this end, for example, power dies may be tested prior to being included in a module, and then metal interconnects (e.g., line widths) of the power bridge(s) can be trimmed or otherwise modified to tune their resistance/inductance prior to package assembly. Package assembly may include attachment (e.g., soldering or sintering) of the second substrate 204 to the first substrate 104, thereby establishing all interconnects of the second substrate simultaneously. Following testing that occurs after such assembly, if needed, the second substrate 204 may be removed and updates may be made, either to the second substrate 204, the first substrate 202, and/or any of the elements on either substrate. In this way, it is possible to provide tuning among individual dies of a single power bridge, as well as between multiple power bridges/power bridge modules.

Described techniques provide two-sided access (that is, to opposed surfaces of the substrates 202, 204) without as much process complexity as conventional package die embedding. Therefore, for example, heatsinks or other heat management structures may be provided with respect to either surface, providing for heat removal by, for example, heat sink attach, thermal interface materials (TIMs), backside silicon fins, or direct contact with a thermally conductive mold compound. Electrical connectivity may also be provided with respect to either or both surfaces, enabling, e.g., connection of both sides of a power die to a single surface of a power package.

FIG. 3 illustrates a view of the example implementation of FIG. 2, taken along line AA. FIG. 3 thus illustrates a view of the second substrate 204 showing an outer edge or perimeter corresponding to, or defining, the area 206 in FIG. 2, as also shown in FIG. 4, below. FIG. 3 also illustrates a gate connection 308a and a source connection 308b of the first semiconductor die 208 as an example embodiment, although the first semiconductor die 208 may represent any type of semiconductor die.

FIG. 4 illustrates a view of the example implementation of FIG. 2, taken along line BB. As noted with respect to FIGS. 2 and 3, the area 206 is defined by, and corresponds to, a surface area of the first substrate 202 that is spanned or covered by the second substrate 204.

FIG. 4 further illustrates that various patterned metals may be configured to electrically connect the first semiconductor die 208 and the second semiconductor die 210 to each other and to various conductive elements on a surface of the first substrate 202 that is outside of the area 206. For example, FIG. 4 illustrates a gate pad 408a and a source pad 408b for the semiconductor die 208, as well as a drain pad 410 for the semiconductor die 410. Either of the gate pad 408a or source pad 408b may be connected via a trace 415 to pad(s) 414b for one or more passive elements. As further illustrated, the gate pad 408a, the pad 414b, an NTC pad 414a, and a connection 222a may be connected to various corresponding contact pads 418 for external connections. Similarly, the connection 222b may be connected by a trace 417 to a contact pad 416, while the drain pad 410 is illustrated as being connected by a trace 419 to a contact pad 414.

FIG. 5A is a top view of a first example semiconductor module 500 made in accordance with the example embodiments of FIGS. 1-4. In FIG. 5A, leads 500a include a plurality of sense, gate, and shunt connections, while leads 500b include ground, output phases, and input power (battery) leads. Individual leads 528, 530, as well as encapsulating mold material 532, are illustrated and described in more detail with respect to FIG. 5B.

In particular, FIG. 5B is a cross-sectional view of the example implementation of FIG. 5A, taken along line 5B. As noted above, FIG. 5B illustrates the lead 528 and the lead 530 of FIG. 5A, as well as a cross-sectional view of the mold material 532.

FIG. 5B further illustrates similar or analogous components corresponding generally to the example of FIG. 2, except as noted below. In the example of FIG. 5B, a substrate 502 represents a first substrate, as an example of the first substrate 102 of FIG. 1 or the first substrate 202 of FIG. 2. A bottom surface of the first substrate 502 may be exposed for electrical and/or thermal connectivity, using an interconnect 501.

A second substrate 504 is positioned over an area 506 of the first substrate 502, defining a span or footprint with respect to the first substrate 502, as discussed above. A first semiconductor die 508 and a second semiconductor die 510, both shown as MOSFETs in the example of FIG. 5B, are positioned on the first substrate 502 and disposed within the area 506.

In the example of FIG. 5B, a conductive element 512a and a conductive element 512b are illustrated as metallization or interconnects. As described above, one or both of the conductive elements 512a, 512b may extend outside of the area 506, e.g., within a plane of the cross section and/or in a direction perpendicular to the plane of the cross section, thereby facilitating and enabling connection(s) between the dies 508, 510 and other elements of the semiconductor module of FIG. 5B. For example, as shown, the conductive element 512b extends to connect, by way of metallization 512c, to lead 530.

An element 514 is illustrated as a negative temperature coefficient/thermistor, also referred to as a NTC sensor 514. The NTC sensor 514 in FIG. 5B is connected to the lead 528 through lead connection 515.

As in FIG. 2, the semiconductor dies 508, 510 in FIG. 5B have different heights. As an example implementation of the height accommodation structure 116 of FIG. 1, a cavity 516a and a cavity 516b are illustrated as containing the dies 508, 510, and having respective depths to ensure that an underlying surface of the second substrate 504 is maintained as being level with, or parallel to, a surface(s) of the first substrate 502, such as a top or bottom surface thereof, and/or parallel with the back layer 501. In particular, the die 508 is taller or higher than the die 510 in FIG. 2, so that the cavity 516a is slightly deeper than the cavity 516b within the second substrate 504. As in FIG. 2, a width and/or length of each of the cavities 516a, 516b may be constructed to fit with, or accommodate, corresponding dimensions of respective dies 508, 510, as well.

In order to provide interconnection of the semiconductor dies 508, 510, to one another and to one or more of the elements 512a, 512b, a dielectric layer 518, metallization layer 519, metallization layer 520, and dielectric layer 521 may be disposed on the second substrate 504. In particular, a portion of the metallization layer 520 may be connected to a direct connection 522a, e.g., may be soldered or sintered to conductive element 512a. Similarly, a portion of the metallization layer 520 may be soldered or sintered to a conductive element 512b that extends outside of the area 506, within the first substrate 502 to connect to the lead 530.

In FIG. 5, similar to FIG. 2, the first substrate 502 has a dielectric layer 503 formed thereon, which has a metallization layer 512 that includes the previous discussed conductive elements 512a, 512b, 512c. Connections 522 (e.g., solder, sinter), including the described connections 522a, 522b connecting the second substrate 504 to the first substrate 502, are formed through dielectric layer 505 to also attach the dies 508, 510 to the first substrate 502, as well as to attach the NTC sensor 514 to the first substrate 502.

Thus, as described with respect to FIGS. 1 and 2, such direct connection of the second substrate 504 to the first substrate 502, in addition to the indirect connection thereof through connection to the dies 508, 510, provides a reliable connection. At the same time, such an approach enables removal of the second substrate 504 if needed to rework any aspect of the second substrate 504 and/or the dies 508, 510 or other elements within the area 506.

Once all testing any associated reworking is completed, mold material 532 may be used to encapsulate the semiconductor module 500. In FIG. 5B, and to be contrasted with the example of FIG. 6B, below, the mold material extends around and completely encases the second substrate 504, i.e., does not expose any portion of the second substrate 504 outside of the semiconductor module 500.

FIG. 6A is a top view of a second example semiconductor module 600 made in accordance with the example embodiments of FIGS. 1-4. In FIG. 6A, leads 600a include a plurality of sense, gate, and shunt connections, while leads 600b include ground, output phases, and input power (battery) leads. FIG. 6A further illustrates heatsinks 626.

FIG. 6B is a cross-sectional view of the example implementation of FIG. 6A, taken along line 6B. FIG. 6B illustrates a lead 628 and a lead 630 of FIG. 6A, as well as a cross-sectional view of mold material 632 and one of the heatsinks 626.

FIG. 6B further illustrates similar or analogous components corresponding generally to the example of FIGS. 2 and 5B, except that the mold material 632 is thinned to expose a surface of the second substrate 604 and thereby enable attachment of the heatsink 626 thereto. In more detail, a first substrate 602 has a bottom surface that is exposed for electrical and/or thermal connectivity, using an interconnect 601.

The second substrate 604 is positioned over an area 606 of the first substrate 602, defining a span or footprint with respect to the first substrate 602, as discussed above. A first semiconductor die 608 and a second semiconductor die 610, both shown as MOSFETs in the example of FIG. 6B, are positioned on the first substrate 602 and disposed within the area 606.

In order to provide interconnection of the semiconductor dies 608, 610, to one another and to one or more of the elements 612a, 612b, 612c, a dielectric layer 618, metallization layer 619, metallization layer 620, and dielectric layer 621 may be disposed on the second substrate 604. In particular, a portion of the metallization layer 620 may be connected to a direct connection 622a, e.g., may be soldered or sintered to conductive element 612a. Similarly, a portion of the metallization layer 620 may be soldered or sintered to a conductive element 612b that extends outside of the area 606, within the first substrate 602 to connect to the lead 630.

The first substrate 602 has a dielectric layer 603 formed thereon, which has a metallization layer 612 that includes the previous discussed conductive elements 612a, 612b, 612c. Connections 622 (e.g., solder, sinter), including the described connections 622a, 622b connecting the second substrate 604 to the first substrate 602, are formed through dielectric layer 605 to also attach the dies 608, 610 to the first substrate 602, as well as to attach an NTC sensor 614, which is connected to the lead 628 through lead connection 615, to the first substrate 602.

As in FIG. 5B, a cavity 616a and a cavity 616b are illustrated as containing the dies 608, 610, and having respective depths to ensure that an underlying surface of the second substrate 604 is maintained as being level with, or parallel to, a surface(s) of the first substrate 602.

Once all testing any associated reworking is completed, mold material 632 may be used to encapsulate the semiconductor module 600. In FIG. 6B, the mold material extends around but does not completely encase the second substrate 604, and exposes a top portion of the second substrate 604 for attachment of the heat sink 626 thereto.

FIG. 7A-7G illustrate example operations for manufacturing the example implementation of FIGS. 2-4. More specifically, FIGS. 7A-7G illustrate example operations for manufacturing the power bridge illustrated as the second substrate 204 of FIGS. 2 and 3, which may be used with the first substrate 202 of FIGS. 2 and 4.

In FIG. 7A, a silicon substrate 704a is covered with a dielectric layer 700. For example, the dielectric layer 703 may include an oxide and/or nitride insulating material, deposited using, e.g., any conventional technique. For example, chemical vapor deposition (CVD) diamond may be used. Insulators used may be electrically insulating and also highly thermally conductive, such as Si₃N₄ or CVD diamond.

In FIG. 7B, the substrate 704a may be patterned using photolithography and etching to form cavities 716a, 716b, to thereby provide substrate 704b with the cavities 716a, 716b. For example, etching may be performed using reactive ion etching (RIE), or using chemical etching techniques.

In FIG. 7C, additional dielectric is added to form dielectric layer 718, corresponding to dielectric layers 118, 218, 518, 618 of FIGS. 1, 2, 5B, and 6B, respectively. In FIG. 7D, a metallization layer 719 is added in any desired pattern, corresponding to metallization layers 219, 519, and 619 of FIGS. 1, 2, 5B, and 6B, respectively. For example, copper, aluminum, or other metal, or combinations thereof, may be added using patterned photolithography and an underlying adhesion layer. For example, the metallization layer 719 may be added using lamination, sputter, printing, plating, or evaporation technologies. Adhesion may utilize Tantalum (Ta), Titanium (Ti), Titanium Nitride (TiN), Titanium Tungsten (TiW), or Chromium (Cr).

In FIG. 7E, dielectric layer 721 is added and patterned using lithography. For example, the dielectric layer 721 may be laminated, spray coated, curtain coated, or spin coated. In FIG. 7F, a solderable/sinterable metal layer 720 may be added, e.g., by photolithography and using, e.g., plating, sputtering, or evaporation). The solderable metal layer 720 may include, e.g, Nickel/Gold, Nickel/Gold/, Nickel/Gold/Tin, Copper/Nickel/Gold, Nickel/Copper, Nickel/Copper/Tin, or Nickel/Vanadium/Silver.

In FIG. 7G, the substrate 704b of FIG. 7F is thinned to form substrate 704. Thinning may be performed using, e.g., grinding or etching while on a glass carrier using bond/debond, or with a tape, grind, detape process. Not shown in FIG. 7G, but discussed above, a backside metal (e.g., for a heatsink) may be provided on the thinned substrate 704 by deposition, or any desired element or material may be added.

The processes of FIGS. 7A-7G may be performed at the power bridge level or at the wafer level. That is, for example, the processes of FIGS. 7A-7G may be performed on a wafer containing multiple future power bridges, which may then be mapped and diced for assembly, to gain economies of scale and other efficiencies. For example, thinning may be performed for all power bridges on a wafer, prior to dicing the wafer, and inspection processes may be performed more efficiently if performed at wafer level.

FIG. 8 is a cross-sectional side view of an alternate example implementation of the semiconductor module of FIG. 1. FIG. 8 illustrates a height adjustment structure 816, as an example of the height adjustment structure 116 of FIG. 1, that includes attachment structures accommodating height differences of underlying components, without requiring one or more cavities to be etched in a substrate 804, e.g., does not require the cavities 216a, 216b of FIG. 2, or the cavities 516a, 516b of FIG. 5B.

In more detail, a first substrate 802 has a bottom surface that is exposed for electrical and/or thermal connectivity, using an interconnect 801. A second substrate 804 is positioned over an area 806 of the first substrate 802, defining a span or footprint with respect to the first substrate 802, as discussed above. A first semiconductor die 808 and a second semiconductor die 810, e.g., IGBTs, are positioned on the first substrate 802 and disposed within the area 806.

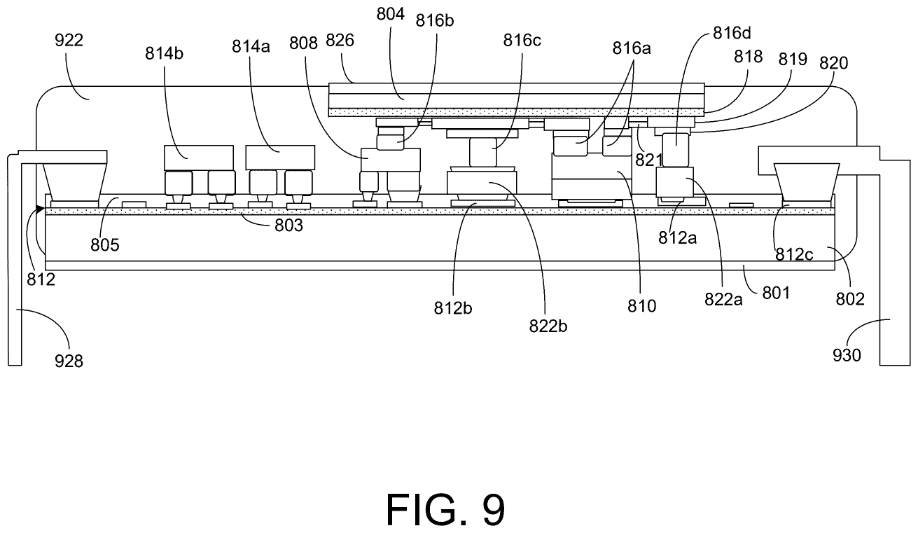

To provide interconnection of the semiconductor dies 808, 810, to one another and to one or more of conductive elements 812a, 812b, 812c, a dielectric layer 818, metallization layer 819, metallization layer 820, and dielectric layer 821 may be disposed on the second substrate 804. A portion of the metallization layer 820 may be connected to height accommodation structures 816a, 816b, 816c, 816d, and thereby to direct connections 822a, 822b and to the dies 808, 810, as shown. For example, the height accommodation structure 816d in FIG. 8 is connected, e.g., soldered or sintered, to connection 822a, and thereby to the conductive element 812a. Similarly, a portion of the metallization layer 820 may be soldered or sintered to height accommodation structure 816c, and thereby to connection 822b to conductive element 812b, which may extend outside of the area 806. Conductive element 812c may be used for lead attachment, as shown in FIG. 9, below.

The first substrate 802 has a dielectric layer 803 formed thereon, which has the metallization layer 812 that includes the previous discussed conductive elements 812a, 812b, 812c. Connections 822 (e.g., solder, sinter), including the described connections 822a, 822b connecting the second substrate 804 to the first substrate 802, are formed through dielectric layer 805, through which the dies 808, 810, as well as an NTC sensor 814a and a passive element 814b, are also attached to the first substrate 802.

As referenced above, in FIG. 8, height accommodation structures 816a and 816b are illustrated as being positioned on the dies 808, 810, and having respective thicknesses to ensure that an underlying surface of the second substrate 804 is maintained as being level with, or parallel to, a surface(s) of the first substrate 802. Additional height accommodation structures 816c and 816d are positioned on connections 822b and 822a, respectively, to ensure planarity of the second substrate 804 as well as reliable connection of the second substrate 804 to the dies 808, 810 and to the first substrate 802.

Some or all of the height accommodation structure 816 may be positioned below the semiconductor dies 808, 810, as well. For example, conductive elements 816e and 816f may be positioned beneath the semiconductor dies 808, 810.

Consequently, the embodiment of FIG. 8 avoids the cost and time associated with forming cavities, while maintaining many or all of the advantages described above. Specifically, the embodiment of FIG. 8 enables use of the patterned second substrate 804 to electrically connect multiple dies, e.g., the dies 808, 810 within a module, while replacing wire bonds, ribbon bonds and/or clips.

In addition to the height accommodation structure(s) 816 of FIG. 8, a topography of such a multi-chip module may be accounted for by, e.g., varying die thicknesses, varying die attach and power bridge attach thicknesses, and/or plating or adding conductive layers to the planar power bridge of FIG. 8.

In addition to attachment of heat sinks, such as a heat sink 826, additional functionality may be provided by adding additional dies or other circuit elements, including another module or package, to an exposed top of the second substrate 804, or within a surface of the second substrate 804 that faces the first substrate 802, as described with respect to FIG. 1.

Thus, the approach of FIG. 8, relative to existing approaches, increases an overall efficiency in assembly and electrical performance of the module of FIG. 8. Line widths may be modified to trim for equivalent inductance across multiple dies in a module, while resistance losses due to electrical crowding of current flowing into a wirebond may be avoided. As with earlier embodiments, the second substrate 804 may be attached simultaneously for expedited assembly (as compared to using multiple different attach processes for wire bonds and clips).

FIG. 9 is a cross-sectional side view of the example implementation of FIG. 8, illustrating an example encapsulation. A separate top view of the example implementation of FIG. 9 is not provided, but would be similar to the example of FIG. 6A.

In FIG. 9, once all testing any associated reworking is completed in the context of FIG. 8, mold material 922 may be used to encapsulate the semiconductor module. In FIG. 9, the mold material 922 extends around but does not completely encase the second substrate 804, and exposes a top portion of the second substrate 804 for attachment of the heat sink 826 thereto.

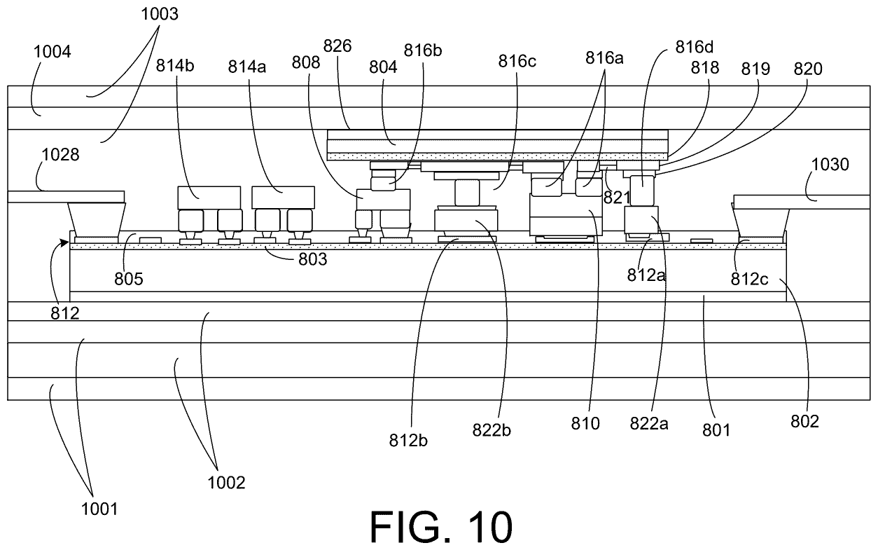

FIG. 10 is a cross-sectional side view of the example implementation of FIG. 8, illustrating a first example of embedded packaging. In FIG. 10, the semiconductor module of FIGS. 8 and 9 is embedded in a package that includes encapsulant 1001 and 1003, which may include, e.g., any plastic, epoxy, ceramic, and/or organic material, such as FR-4 as mentioned above. Conductive lines 1002 and 1004 may represent any power and/or signal lines. Leads 1028, 1030, similar to leads 928, 930 of FIG. 9, may be used for external connection of the embedded package of FIG. 10. As may be appreciated from the above description, it is straightforward to connect the conductive lines 1002, 1004, because the described power bridge packaging approach enables two-sided connectivity.

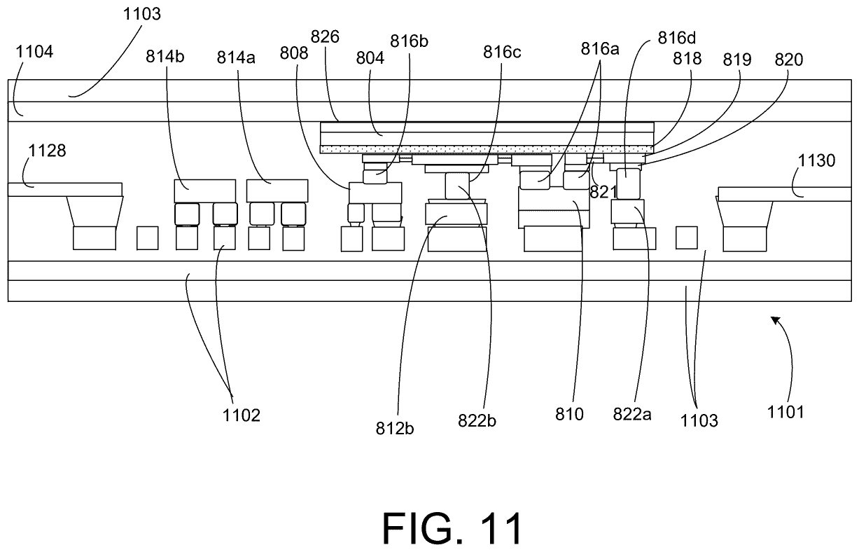

FIG. 11 is a cross-sectional side view of the example implementation of FIG. 8, illustrating a second example of embedded packaging. In FIG. 11, the semiconductor module of FIGS. 8-10 is embedded in a package that includes encapsulant 1103, which may include, e.g., any plastic, epoxy, ceramic, and/or organic material, such as FR-4 as mentioned above. A first substrate 1101 is illustrated as a ceramic substrate that includes or embeds conductive lines 1102 that may represent power or signal lines, while conductive line 1104 is illustrated as being connected to a top surface of the second substrate 804. Leads 1128, 1130, similar to leads 928/930 of FIG. 9 and leads 1028/1030 of FIG. 10, may be used for external connection of the embedded package of FIG. 11.

In FIGS. 10 and 11, a power bridge can such as the second substrate 804 and associated patterning may be incorporated into an embedded package using various techniques. For example, the first substrate 802 and the second substrate 804 may be assembled and then embedded into an organic substrate, such as the material 1003 in FIG. 10, or an embedded organic substrate may be used as the first/lower substrate, with the power bridge applied thereto followed by encapsulation to form an embedded package, such as in FIG. 11.

The embedded packages of FIGS. 10 and 11 thus provide enhanced functionality for a given package footprint, relative to existing packaging techniques that do not use embedding. At the same time, these approaches add significant functionality over existing embedded package solutions, as well.

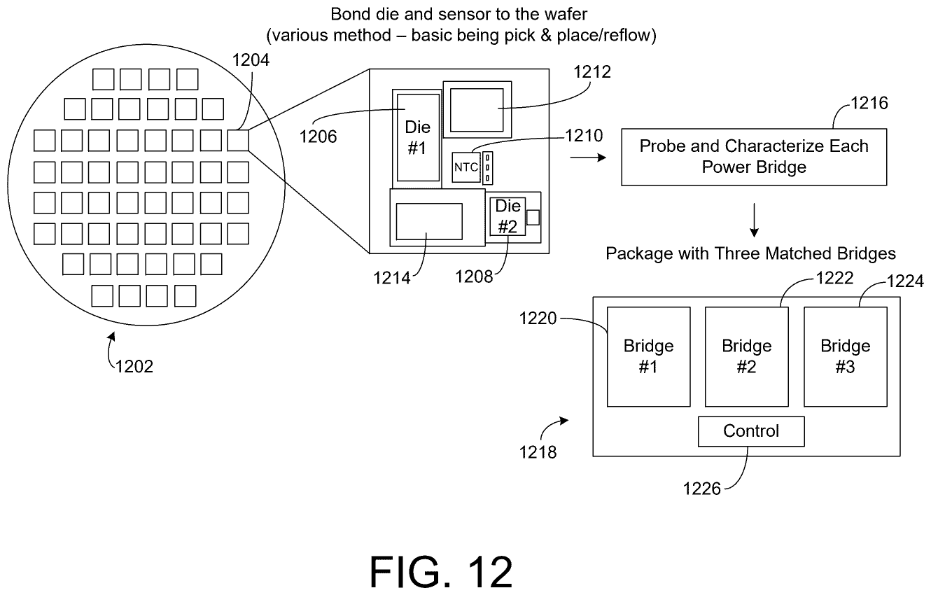

FIG. 12 is a process flow for wafer-level processing of power bridges of FIG. 1. In FIG. 12, a wafer 1202 includes multiple reticle fields or panels 1204, each of which will become or provide a first substrate, such as the first substrates 102, 202, 502, 602, or 802.

Thus, as shown, the panel 1204 provides a substrate, on which various elements may be formed, including a first die 1206, a second die 1208, a NTC sensor 1210, and other elements 1212, 1214. For example, the dies 1206, 1208 and sensor 1210 may be bonded to the underlying panel 1204 using various methods, e.g., pick and place with reflow.

Power bridges formed, e.g., using the processes of FIGS. 7A-7G, may be probed and characterized (1216), so that a package 1218 with three matched power bridges 1220, 1222, and 1224 may then be formed, including a separate control element 1226. The various processing steps of FIG. 12 may be performed on the wafer 1202 prior to dicing/singulation, or may be performed after dicing/singulation.

As shown and described, the package 1218 may thus have power bridges 1220, 1222, 1224 that are tuned individually and as a group. Moreover, all of the above advantages, including, e.g., including one or more devices and/or heatsinks in or on one or more of the power bridges 1220, 1222, 1224, may be present in the example of FIG. 12. Two-sided electrical and/or thermal connectivity may be provided by the final package 1218, as well.

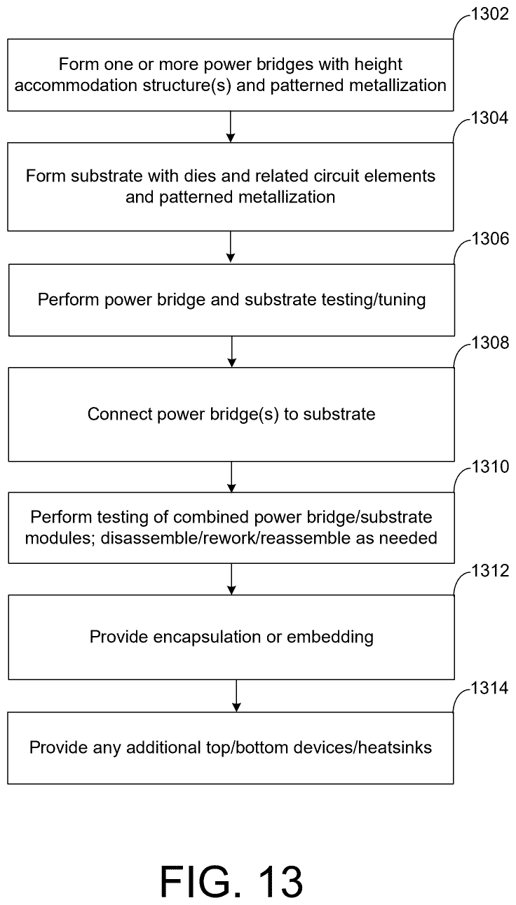

FIG. 13 is a flowchart illustrating example manufacturing techniques for a semiconductor package that includes the power bridges of FIG. 1. In the example of FIG. 13, one or more power bridges are formed, including, e.g., height accommodation structures and patterned metallizations (1302). For example, the process of FIGS. 7A-7G may be used. The height accommodation structures may include cavities and/or planarization structures, and/or may include variations in die thickness, power bridge thickness, die attach or power bridge attach thickness, and/or adding conductive layers to the power bridge. The patterned metallization may be formed using sputtering, plating, or printing, or any available technique(s).

The power bridge(s) may also be formed with devices formed therein or thereon. Such devices may range from simple devices, such as a capacitor or inductor, to more complex devices, such as MOSFETS or other active devices, temperature sensors, drivers, or other devices, or various combinations thereof. Such devices may be fabricated internally in conjunction with fabrication of the power bridge, and/or may be attached after fabrication of the power bridge. Such approaches add functionality to the resulting module to be formed, while minimizing a footprint of the module.

Power bridges may be assembled on a Si wafer, e.g., do not need to be assembled onto a rectangular/square module. Such a wafer may be singulated before or after testing of the individual modules. In some embodiments, power bridges may be made using low cost 300 mm Si, without expensive epitaxial layer(s) (unless, e.g., the Si substrate of the power bridge has active devices that require an epitaxial layer).

Processing in wafer form allows for photolithography, plated metallization, evaporated or sputtered metal layers, etching, oxide, Si etch (wet and dry), laser singulation, saw singulation, and other standard wafer processes and infrastructure to be used. Metallization can be modified or tuned for each module if desired. An entire wafer can be encapsulated with underfill material, epoxy mold compounds, transfer molded mold compounds, or metal casings. Wafer processing tools and infrastructure may be used to form the interconnect before and/or after the devices have been mounted to the substrate. Full thickness wafers can be used, or wafers on carrier substrate.

A substrate to which the power bridge(s) will be attached is formed, including related circuit elements and patterned metallization (1304). For example, devices may be formed on a panel(s) of a wafer, as described and illustrated with respect to FIG. 12. The patterned metallizations of the power bridge and the substrate may correspond to one another, as shown in FIGS. 3 and 4. Portions of the height accommodation structure (such as conductive plating/layers) may be formed initially on the substrate.

Testing/tuning may be performed on the power bridge(s) and substrate(s) (1306). Such testing may vary based on included features of the power bridge(s)/substrate(s), but generally includes tests for connectivity, physical structure, and functionality.

The one or more power bridge(s) may then be connected to the substrate (1308). For example, multiple power bridges may be attached to an underlying substrate, as shown in FIG. 12. For example, pick-and-place or other tools may be used. The power bridges may be soldered or sintered to the underlying substrate.

Testing of combined power bridge(s)/substrate modules may then be performed, and, as needed, one or more of the power bridge(s) may be disassembled to enable rework of either the power bridge or the substrate elements, followed by reassembly (1310). In this way, collective tuning of across multiple power bridges may be provided in an efficient and practical manner.

Encapsulation or embedding may then be provided (1312). For example, a mold material may be used for encapsulation, or an organic material may be used for embedding. Atop and/or bottom of the resulting encapsulated/embedded module may be exposed for electrical and/or thermal connectivity.

If desired, any additional devices or heatsinks may thus be provided to the top and/or bottom of the module (1314). Consequently, the module may be formed with a compact footprint and size, and in a reliable manner that provides a high degree of confidence in the functionality of the final product.

Singulation may be performed at any suitable and desired stage. For example, singulation of the wafer 1202 may occur prior to, or after, placement of one or more power bridges on individual ones of panel(s) 1204.

In various embodiments, a die may be mounted to a power bridge, which is then mounted to a wafer/substrate, in which case, probing of power bridge assemblies may be performed prior to dicing of the power bridge wafer. Conversely, as described earlier, the die may be mounted to the wafer/substrate, and then the power bridge added thereto.

Described techniques may be used to replace wirebonds and other conventional interconnect techniques in any context, and are well-suited to power applications, due to, e.g., improvements to electrical and thermal performance as described herein. Described techniques can be performed using standard semiconductor processing, such as lithography patterning, and can also utilize solder or polymer jetting, or screening through a metal mask.

In some implementations, soldering can be, or can include, a process of joining two surfaces (e.g., metal surfaces) together using a molten filler metal (e.g., metal alloy, Tin (Sn), Lead (Pb), Silver (Ag), Copper (Cu)) that can be referred to as a solder.

In some implementations, sintering can be or can include a process of fusing particles together into one solid mass by using, for example, a combination of pressure and/or heat without melting the materials. In some implementations, sintering can include making a material (e.g., a powdered material) coalesce into a solid or porous mass by heating it, and usually also compressing the material, without liquefaction. In some implementations, materials that can be used for sintering can include metals such as silver (Ag), copper (Cu) and/or metal alloys. In some implementations, sintered connections can have desirable electrical and/or thermal conductivity, durability, and a relatively high melting temperature.

In some implementations, one or more of the components described herein can be coupled using materials such as, for example, a solder, a sintering (e.g., silver, copper) material, and/or other metal-to-metal type bonding materials.

In some implementations, a coupling of components can be performed using, for example, a solder process, a sintering process (e.g., a silver sintering process, a copper sintering process), and/or other metal-to-metal type bonding processes.

In some implementations, the direct bonded metal (DBM) substrate (e.g., direct bonded copper (DBC)) can include an insulating layer disposed between a first metal layer and a second metal layer. The insulating layer can be, for example, a ceramic layer. In some implementations, the insulating layer can be or can include, for example, a ceramic material such as alumina (Al₂O₃) or aluminum nitride (AlN)).

In some implementations, a DBM substrate can be formed by bonding one or more of the metal layers (e.g., first metal layer, second metal layer) to the insulating layer. In some implementations, one or more of the metal layers can be bonded to the insulating layer using, for example, a high-temperature process.

In some implementations, the first metal layer and/or the second metal layer of the DBM substrate can be or can function as a heat sink. In some implementations, the first metal layer and/or the second metal layer can be coupled to a heat sink. In some implementations, at least a portion of one or more of the first metal layer or the second metal layer can be exposed through a molding material.

In some implementations, the first metal layer and/or the second metal layer of the DBM substrate can be or can include a patterned metal layer including one or more electrically conductive traces. In some implementations, the first metal layer and/or the second metal layer can be or can include a patterned layer configured to form one or more electrical circuits, one or more conductive blind and/or through vias, and/or so forth.

In some implementations, a DBM substrate can be, or can include, a direct bonded copper (DBC) substrate (e.g., a DBM with copper metal layers). In some implementations, such as in DBC substrate implementations, the first metal layer and/or the second metal layer is a copper layer.

In some implementations, one or more semiconductor die (e.g., one or more semiconductor components) can be, or can include, a power semiconductor die. In some implementations, one or more semiconductor die can be (e.g., can be a portion of), or can include, one or more of a metal-oxide-semiconductor field-effect transistor (MOSFET) device, an insulated-gate bipolar transistor (IGBT), an integrated circuit (IC), an inverter, a power conversion circuit, a bridge circuit, a fast recovery diode (FRDs), a diode, and/or so forth. In some implementations, one or more semiconductor die can be (e.g., can be a portion of), or can include, a component for an electrical vehicle (EV).

More than one semiconductor die can be included in the implementations described herein. In some implementations, different semiconductor die (when more than one semiconductor die is included in some of the implementations) can be fabricated using different semiconductor substrates (e.g., a silicon carbide (SiC) substrate, a silicon (Si) substrate, a gallium nitride (GaN) substrate). In other words, different semiconductor die may, for example, be fabricated on different semiconductor wafers or materials. This can be referred to as a hybrid die configuration. For example, a first semiconductor die can be formed using a SiC substrate and a second semiconductor die (separate from the first semiconductor die) can be formed using a silicon substrate. As another example, an IGBT can be fabricated using a SiC substrate, while a controller can be fabricated using a silicon substrate.

In example implementations, a first semiconductor die may be connected to a second of the semiconductor die, for example, by an electrical connection (e.g., a wire bond, an electrical clip) extending directly from the first die to the second die, or connected through a trace formed in the first conductive layer (e.g., a metal layer) of an electronic power substrate. The first of the plurality of semiconductor die may be also connected to lead frame posts by electrical connections such as wirebonds or clips.

In example implementations, a package (e.g., a power module) can be a hybrid device package that includes a semiconductor die or a plurality of semiconductor die that are integrated onto to a unifying electronic power substrate (e.g., a ceramic substrate, a DBM or DBC substrate, an AMB substrate). In some implementations, multiple semiconductor devices (e.g., can be fabricated on the same substrate such as a SiC substrate) suitable for high power applications.

Although referred to, by way of example, as a leadframe in at least some portions of this detailed description, the leadframe can include any type of conductive portion of a package (e.g., conductive portion, conductive terminal) that can provide an external connection point from a package. Accordingly, the leadframe can be referred to as a conductive portion of the package.

In some implementations, one or more portions of a leadframe can be coupled to a pad (e.g., a bond pad) on at least a portion of a DBM substrate.

The semiconductor device packages described herein can include a plurality of signal terminals. The plurality of signal terminals can be power terminals, input signal terminals, output signal terminals, and so forth. In some implementations, the plurality of signal terminals can be included in a leadframe. In some implementations, a leadframe can include any type of conductive portion of a package (e.g., conductive portion, conductive terminal) that can provide an external connection point from a package. Accordingly, a leadframe can be referred to as a conductive portion of a package or assembly. In some implementations, one or more portions of a leadframe can be coupled to a pad (e.g., a bond pad) on at least a portion of a DBM substrate and/or a semiconductor die.

In some implementations, a molding compound (e.g., molding material or compound, an encapsulation material) can be or can include a non-conducting layer/material. In some implementations, the molding compound is a non-conducting material, such as an epoxy, which can be formed (applied, etc.) using a transfer molding process or a compression molding process. In some implementations, the molding compound can include a separate plastic housing that is included in the semiconductor device assembly.

One or more wire bonds, which can be included in at least some of the implementations described herein, can be replaced with a conductive component. For example, in some implementations, one or more wire bonds can be replaced with a conductive clip. The conductive clip can be coupled to another component (e.g., an attach pad, a leadframe, a semiconductor die, and/or so forth) using, for example, a solder (e.g., a soldering process), a sintered coupling (e.g., a sintering process), a weld, and/or so forth. In some implementations, one or more wire bonds and/or clips can function as an input and/or output power terminal, a signal terminal, a power terminal, and/or so forth.

In some implementations, one or more semiconductor die associated with the implementations described herein can be embedded within a layer (rather than surface mounted). For example, one or more semiconductor die can be disposed within a recess (also can be, or can be referred to as a cavity) of a layer (e.g., a substrate, a printed circuit board, a conductive layer, an insulating layer).

In some implementations, a module (e.g., a package including a semiconductor device) can be included in another module. The module can be referred to as a package. For example, one or more modules can be one or more sub modules included within another module. In other words, a first module can be included as a sub module within a second module.

In some implementations, a spacer material can be an epoxy, a silicone adhesive, a conductive material, a non-conductive material, an organic material, a semiconductor material, a metal alloy, a metal foam, a phase change material, etc.

In the present description, semiconductor die(s) that may be used may be any of a wide variety including, by non-limiting example, power semiconductor die, diodes, metal oxide field effect transistors (MOSFETs), insulated gate bipolar junction transistors (IGBTs), hybrid devices, rectifiers, random access memory, high-electron-mobility transistors, image sensors, wide bandgap (WBG) semiconductor devices, hybrid devices, or any other semiconductor die/device type. Any of a wide variety of semiconductor substrate types may be employed for the semiconductor die packaged using the semiconductor package designs disclosed in this document including, by non-limiting example, silicon, silicon carbide, gallium arsenide, gallium nitride, silicon on insulator, ruby, sapphire, diamond, or any other semiconductor material type. A wide variety of semiconductor package configurations may be formed using the principles disclosed herein.

It will be understood that, in the foregoing description, when an element, such as a layer, a region, a substrate, or component is referred to as being on, connected to, electrically connected to, coupled to, or electrically coupled to another element, it may be directly on, connected or coupled to the other element, or one or more intervening elements may be present. In contrast, when an element is referred to as being directly on, directly connected to or directly coupled to another element or layer, there are no intervening elements or layers present. Although the terms directly on, directly connected to, or directly coupled to may not be used throughout the detailed description, elements that are shown as being directly on, directly connected or directly coupled can be referred to as such. The claims of the application, if any, may be amended to recite exemplary relationships described in the specification or shown in the figures.

As used in the specification and claims, a singular form may, unless definitely indicating a particular case in terms of the context, include a plural form. Spatially relative terms (e.g., over, above, upper, under, beneath, below, lower, and so forth) are intended to encompass different orientations of the device in use or operation in addition to the orientation depicted in the figures. In some implementations, the relative terms above and below can, respectively, include vertically above and vertically below. In some implementations, the term adjacent can include laterally adjacent to or horizontally adjacent to.

Some implementations may be implemented using various semiconductor processing and/or packaging techniques. Some implementations may be implemented using various types of semiconductor processing techniques associated with semiconductor substrates including, but not limited to, for example, Silicon (Si), Gallium Arsenide (GaAs), Gallium Nitride (GaN), Silicon Carbide (SiC) and/or so forth.

The following is a list of enumerated example embodiments.
1. A semiconductor module, comprising:
   a first substrate having a first substrate surface that includes an area;
   a first semiconductor die disposed within the area on the first substrate surface;
   a second semiconductor die disposed within the area on the first substrate surface; and
   a second substrate that has a second substrate surface that spans the area and faces the first semiconductor die, the second semiconductor die, and the area, the second substrate surface having a dielectric layer formed thereon with a metallization layer formed on the dielectric layer that includes patterned metals configured to electrically connect the first semiconductor die and the second semiconductor die to each other and to at least one conductive element on the first substrate surface that is outside of the area.
2. The semiconductor module of example 1, wherein the second substrate comprises at least one of Silicon or Gallium Nitride.
3. The semiconductor module of example 1, wherein the first semiconductor die has a first height and the second semiconductor die has a second height that is different from the first height, and further comprising:
   a height adjustment structure between the second substrate and both of the first semiconductor die and the second semiconductor die that maintains opposed outer surfaces of the semiconductor module in parallel with one another.
4. The semiconductor module of example 3, wherein the height adjustment structure includes a first cavity and a second cavity formed in the second substrate and having a first depth and a second depth, respectively, and further wherein the first semiconductor die is disposed within the first cavity and the second semiconductor die is disposed within the second cavity.
5. The semiconductor module of example 4, wherein the first cavity and the second cavity have sloped walls and with the dielectric layer and the metallization layer formed thereon.
6. The semiconductor module of example 3, wherein the height adjustment structure includes at least one conductive layer disposed between at least one of the first semiconductor die and the second semiconductor die, and having a thickness that maintains the opposed outer surfaces of the semiconductor module in parallel with one another.
7. The semiconductor module of example 1, wherein the second substrate has an outer surface opposed to the second substrate surface, and further comprising a device formed on the outer surface.
8. The semiconductor module of example 1, wherein the second substrate has an outer surface opposed to the second substrate surface, and further comprising a heatsink formed on the outer surface.
9. The semiconductor module of example 1, wherein the second substrate is directly connected to the first substrate.
10. The semiconductor module of example 1, further comprising a sensor disposed on the second substrate.
11. A semiconductor module, comprising:
   a first substrate having a first substrate surface that includes an area;
   a first semiconductor die disposed within the area on the first substrate surface and having a first height;
   a second semiconductor die disposed within the area on the first substrate surface and having a second height;
   a second substrate that has a second substrate surface that spans the area and faces the first semiconductor die, the second semiconductor die, and the area, the second substrate surface having a dielectric layer formed thereon with a metallization layer formed on the dielectric layer that includes patterned metals configured to electrically connect the first semiconductor die and the second semiconductor die to each other; and
   a height adjustment structure between the second substrate and both of the first semiconductor die and the second semiconductor die that maintains opposed outer surfaces of the semiconductor module in parallel with one another.
12. The semiconductor module of example 11, wherein the second substrate is directly connected to the first substrate and the patterned metals are configured to electrically connect at least one of the first semiconductor die and the second semiconductor die to at least one conductive element on the first substrate surface that is outside of the area.
13. The semiconductor module of example 12, wherein the height adjustment structure includes a first cavity and a second cavity formed in the second substrate and having a first depth and a second depth, respectively, and further wherein the first semiconductor die is disposed within the first cavity and the second semiconductor die is disposed within the second cavity.
14. The semiconductor module of example 13, wherein the first cavity and the second cavity have sloped walls and with the dielectric layer and the metallization layer formed thereon.
15. The semiconductor module of example 11, wherein the height adjustment structure includes at least one conductive layer disposed between at least one of the first semiconductor die and the second semiconductor die, and having a thickness that maintains the opposed outer surfaces of the semiconductor module in parallel with one another.
16. The semiconductor module of example 11, wherein the second substrate comprises at least one of Silicon or Gallium Nitride.
17. A method of making a semiconductor module, comprising:
   disposing, on a first substrate having a first substrate surface that includes an area, a first semiconductor die and a second semiconductor die disposed within the area on the first substrate surface;
   forming a second substrate with a second substrate surface having a dielectric layer formed thereon with a metallization layer formed on the dielectric layer that includes patterned metals; and
   connecting the second substrate to the first substrate, with the second substrate surface of the second substrate spanning the area and facing the first semiconductor die and a second semiconductor die within the area, and with the patterned metals configured to electrically connect the first semiconductor die and the second semiconductor die to each other and to at least one conductive element on the first substrate surface that is outside of the area.
18. The method of example 17, further comprising:
   providing a height adjustment structure between the second substrate and both of the first semiconductor die and the second semiconductor die that maintains opposed outer surfaces of the semiconductor module in parallel with one another.
19. The method of example 18, further comprising providing the height adjustment structure including:
   forming a first cavity and a second cavity in the second substrate with a first depth and a second depth, respectively;
   disposing the first semiconductor die within the first cavity; and
   disposing the second semiconductor die within the second cavity.
20. The method of example 18, further comprising providing the height adjustment structure including:
   providing at least one conductive layer disposed between at least one of the first semiconductor die and the second semiconductor die, with a thickness that maintains the opposed outer surfaces of the semiconductor module in parallel with one another.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the implementations. It should be understood that they have been presented by way of example only, not limitation, and various changes in form and details may be made. Any portion of the apparatus and/or methods described herein may be combined in any combination, except mutually exclusive combinations. The implementations described herein can include various combinations and/or sub-combinations of the functions, components and/or features of the different implementations described.

While certain features of the described implementations have been illustrated as described herein, many modifications, substitutions, changes and equivalents will now occur to those skilled in the art. It is, therefore, to be understood that the appended claims are intended to cover all such modifications and changes as fall within the scope of the embodiments.

What is claimed is:

1. A semiconductor module, comprising:
a first substrate having a first substrate surface that includes an area;
a first semiconductor die disposed within the area on the first substrate surface;
a second semiconductor die disposed within the area on the first substrate surface; and
a second substrate that has a second substrate surface that spans the area and faces the first semiconductor die, the second semiconductor die, and the area, the second substrate surface having a dielectric layer formed thereon with a metallization layer formed on the dielectric layer that includes patterned metals configured to electrically connect the first semiconductor die and the second semiconductor die to each other and to at least one conductive element on the first substrate surface that is outside of the area.

2. The semiconductor module of claim 1, wherein the second substrate comprises at least one of Silicon or Gallium Nitride.

3. The semiconductor module of claim 1, wherein the first semiconductor die has a first height and the second semiconductor die has a second height that is different from the first height, and further comprising:
a height adjustment structure between the second substrate and both of the first semiconductor die and the second semiconductor die that maintains opposed outer surfaces of the semiconductor module in parallel with one another.

4. The semiconductor module of claim 3, wherein the height adjustment structure includes a first cavity and a second cavity formed in the second substrate and having a first depth and a second depth, respectively, and further wherein the first semiconductor die is disposed within the first cavity and the second semiconductor die is disposed within the second cavity.

5. The semiconductor module of claim 4, wherein the first cavity and the second cavity have sloped walls and with the dielectric layer and the metallization layer formed thereon.

6. The semiconductor module of claim 3, wherein the height adjustment structure includes at least one conductive layer disposed between at least one of the first semiconductor die and the second semiconductor die, and having a thickness that maintains the opposed outer surfaces of the semiconductor module in parallel with one another.

7. The semiconductor module of claim 1, wherein the second substrate has an outer surface opposed to the second substrate surface, and further comprising a device formed on the outer surface.

8. The semiconductor module of claim 1, wherein the second substrate has an outer surface opposed to the second substrate surface, and further comprising a heatsink formed on the outer surface.

9. The semiconductor module of claim 1, wherein the second substrate is directly connected to the first substrate.

10. The semiconductor module of claim 1, further comprising a sensor disposed on the second substrate.

11. A semiconductor module, comprising:
a first substrate having a first substrate surface that includes an area;
a first semiconductor die disposed within the area on the first substrate surface and having a first height;
a second semiconductor die disposed within the area on the first substrate surface and having a second height;
a second substrate that has a second substrate surface that spans the area and faces the first semiconductor die, the second semiconductor die, and the area, the second substrate surface having a dielectric layer formed thereon with a metallization layer formed on the dielectric layer that includes patterned metals configured to electrically connect the first semiconductor die and the second semiconductor die to each other; and
a height adjustment structure between the second substrate and both of the first semiconductor die and the second semiconductor die that maintains opposed outer surfaces of the semiconductor module in parallel with one another.

12. The semiconductor module of claim 11, wherein the second substrate is directly connected to the first substrate and the patterned metals are configured to electrically connect at least one of the first semiconductor die and the second semiconductor die to at least one conductive element on the first substrate surface that is outside of the area.

13. The semiconductor module of claim 12, wherein the height adjustment structure includes a first cavity and a second cavity formed in the second substrate and having a first depth and a second depth, respectively, and further wherein the first semiconductor die is disposed within the first cavity and the second semiconductor die is disposed within the second cavity.

14. The semiconductor module of claim 13, wherein the first cavity and the second cavity have sloped walls and with the dielectric layer and the metallization layer formed thereon.

15. The semiconductor module of claim 11, wherein the height adjustment structure includes at least one conductive layer disposed between at least one of the first semiconductor die and the second semiconductor die, and having a thickness that maintains the opposed outer surfaces of the semiconductor module in parallel with one another.

16. The semiconductor module of claim 11, wherein the second substrate comprises at least one of Silicon or Gallium Nitride.

17. A method of making a semiconductor module, comprising:
disposing, on a first substrate having a first substrate surface that includes an area, a first semiconductor die and a second semiconductor die disposed within the area on the first substrate surface;
forming a second substrate with a second substrate surface having a dielectric layer formed thereon with a metallization layer formed on the dielectric layer that includes patterned metals; and
connecting the second substrate to the first substrate, with the second substrate surface of the second substrate spanning the area and facing the first semiconductor die and a second semiconductor die within the area, and with the patterned metals configured to electrically connect the first semiconductor die and the second semiconductor die to each other and to at least one conductive element on the first substrate surface that is outside of the area.

18. The method of claim 17, further comprising:
providing a height adjustment structure between the second substrate and both of the first semiconductor die and the second semiconductor die that maintains opposed outer surfaces of the semiconductor module in parallel with one another.

19. The method of claim 18, further comprising providing the height adjustment structure including:
forming a first cavity and a second cavity in the second substrate with a first depth and a second depth, respectively;
disposing the first semiconductor die within the first cavity; and
disposing the second semiconductor die within the second cavity.

20. The method of claim 18, further comprising providing the height adjustment structure including:
providing at least one conductive layer disposed between at least one of the first semiconductor die and the second semiconductor die, with a thickness that maintains the opposed outer surfaces of the semiconductor module in parallel with one another.
